(19) United States
(12) Patent Application Publication
(10) Pub. No.: US 2025/0153481 A1
(43) Pub. Date: May 15, 2025

(54) METHOD AND SUBSTRATE SYSTEM FOR THE SEPARATION OF CARRIER SUBSTRATES

(71) Applicant: EV Group E. Thallner GmbH, St. Florian am Inn (AT)

(72) Inventors: Markus Wimplinger, St. Florian am Inn (AT); Thomas Uhrmann, St. Florian am Inn (AT); Jurgen Burggraf, St. Florian am Inn (AT); Boris Povazay, St. Florian am Inn (AT); Bernhard Thallner, St. Florian am Inn (AT)

(73) Assignee: EV Group E. Thallner GmbH, St. Florian am Inn (AT)

(21) Appl. No.: 18/839,458

(22) PCT Filed: Mar. 25, 2022
(86) PCT No.: PCT/EP2022/057867

§ 371 Date: Aug. 19, 2024

(51) Int. Cl. B32B 43/00; H01L 21/683

(52) U.S. Cl. CPC B32B 43/006; H01L 21/6835; B32B 2457/14

(57) ABSTRACT

The invention relates to a method and a substrate system for the separation of a carrier substrate from a substrate, in particular a product substrate, by irradiation of the separating layer.

### FIELD OF THE INVENTION

The present invention relates to a method, a device and substrate system for separating carrier substrates from further layers. The carrier substrate can be separated in different processes for the processing of substrates, for example in the debonding or in the transfer of substrates.

### BACKGROUND OF THE INVENTION

In the semiconductor industry, it is increasingly important to develop methods and devices, with the aid of which on the one hand a high degree of adhesion can be produced between surfaces, and on the other hand the adhesion can be prevented again if required. Such methods and devices for the processing of substrates are used chiefly for two different techniques, the layer transfer and the bonding or debonding of substrates.

In the case of the layer transfer, in particular inorganic, mainly very thin layers in themselves not mechanically stable are transferred between self-supporting substrates. The inorganic layers are produced for example on special growth substrates, but then must be transferred onto another substrate, in particular a product substrate, in order to be able to meet their functional properties there. In the rarest cases, the growth substrate and the product substrate are identical.

In the prior art, so-called release layers or separating layers are used in order to carry out a locally targeted separation of the useful layer from the carrier substrate. Until today, organic polymer layers are used as bonding layers, which expensively make an additional cleaning step necessary in the transfer of the useful substrate and increase the contamination.

In the bonding and debonding of substrates, two substrates are first joined together, in order that one of the two substrates, which usually does not have sufficient intrinsic stability for the process on account of a smaller thickness or lower strength, can be processed supported by the second substrate. The processed substrate is called the product substrate, the supporting substrate being called the carrier substrate. Polymers are predominantly used to produce a so-called temporary bond, i.e. a bond which can be released without destruction. For this purpose, at least one polymer is deposited on a substrate by a process, in particular a centrifugal coating process. The carrier substrate is chiefly coated with the polymer (separating layer) and the carrier substrate is bonded to the product substrate. After the bonding of the product substrate to the carrier substrate, the product substrate is further processed in order to be separated from the carrier substrate again in a subsequent process step. There are different methods in the prior art for the separation of the carrier substrate.

In the early years, the carrier substrate was usually coated all over with the polymer. A very good adhesion between the carrier substrate and the product substrate thus arose. If the product substrate has elevations, for example solder bumps, dies or chips, they can be embedded in the polymer, as long as the polymer layer functioning as a separating layer has a suitable layer thickness. The drawback with this method is encountered in the release of the carrier substrate from the product substrate. For the separation, the polymer layer has to be acted upon over the whole area, so that the complete separation proves to be more complex, amongst other things with a plurality of processing steps. The adhesive force of the adhesive layer can be reduced so far with a chemical, which reaches the adhesive layer laterally or through the carrier substrate, that a mechanical separation is enabled. The action of the chemical on the adhesive layer preferably takes place at raised temperatures.

With the separation of a polymer layer over the full area, there is also a higher energy requirement (e.g. heat, ultrasound) or solvent requirement during the removal of the adhesive materials and thus also higher costs. The separation itself is controlled in this process preferably by release forces normal to the substrate surface.

An alternative development is the so-called “slide-off debonding”. In this method, a device is used which fixes the product substrate and the carrier substrate over the whole area with in each case a substrate holder. The two substrate holders are then moved towards one another in parallel, so that the substrates are sheared off from one another via forces along the adhesive surface. For this purpose, it is necessary to heat the polymer layer lying in between. The polymer layer thus softens and loses its adhesive strength. The advantage of this method consists in the fact that solvents and ultrasound can be completely dispensed with. A drawback is that the debonding still has to be carried out at raised temperature.

Alternative methods for debonding dispense with the use of a raised temperature and only make use of a solvent, which attacks the polymer from the periphery of the two substrates. The action of the solvent can be accelerated by means of ultrasound. The dissolved polymer is preferably carried away from the substrate stack by a revolution of the solvent and preferably continuously removed from the solvent bath. It is also possible to inject the solvent solely laterally onto the polymer and to remove it by means of a solvent jet.

A further development of the solvent process is the so-called ZoneBond™ method, which is described in publication WO 2009094558A2. This is a method in which a carrier substrate has to be specially prepared. The carrier substrate consists of two different zones. The central zone, which occupies the largest area, is coated with the aid of an anti-sticking layer and exhibits a low degree of adhesion to any kind of polymer. The second zone surrounds the first zone in a circular manner usually as a closed ring and reaches up to the edge of the carrier substrate. The thickness of the circular ring amounts to only a few millimetres. This very small area is sufficient to fix the polymer and therefore the product substrate bonded to the carrier substrate over the whole area. The interior is thereby fixed during the processing steps by the air pressure and the sealing of the sides. It is advantageous that, for the debonding, only the polymer from the second, more easily accessible zone has to be removed, in order to enable debonding of the carrier substrate from the product substrate.

A further development consisted in the use of photosensitive separating layers. These were usually deposited on a, in particular transparent, carrier substrate. The carrier substrate was then coated with a polymer layer and bonded to a product substrate. After the product substrate had finished being processed, by irradiating the separating layer through the carrier substrate, the latter could be released from the product substrate. Such processes are described for example in publications US20150035554A1, US20160133486 and US20160133495A1. A special embodiment of this method, in which the separating layer was not deposited on the carrier substrate, but on the product substrate, can be found in publication WO 2017076682 A1.

The mentioned processes can be combined with one another. For example, a change of orientation of the product substrate can also be carried out. Since the carrier substrates are flipped in this process, one also speaks of a carrier flip. For example, WO2011120537A1 shows a process, in which the product substrate is fixed on a first carrier by means of a polymer layer and then processed. After the processing, in particular back-thinning, the product substrate is very thin and for further use of the other substrate side is bonded on a second carrier substrate. The transfer of the product substrate takes place via two polymer layers. The first carrier substrate, after the fixing of the product substrate on the second carrier substrate, has to be separated from the product substrate.

All the mentioned processes are chiefly based on the fact that some part, but in particular a layer, is influenced such that the adhesion to other parts is reduced, in particular completely eliminated. In other words, the adhesive properties of the separating layer are reduced.

The devices and methods described in the prior art thus describe a separation process, which provides organic layers, in particular polymer layers, as separating layers or combines organic bonding layers with inorganic separating layers. The use of polymers as bonding layers and/or separating layers, which temporarily join two substrates together, has a number of drawbacks. The polymers are long-chain molecules, whose main component is carbon. Organic materials are often a drawback and undesired in the semiconductor industry, since they can contaminate a clean room environment, in particular the devices in which the substrates are processed. Furthermore, the polymers have the drawback that they maintain their adhesive property only up to a relatively low temperature, which represents an advantage for the debonding, but is disadvantageous if the product substrate has to be processed on the carrier substrate at high temperatures. Apart from the low temperature resistance of organic layers, organic separating layers often have to be applied relatively thick in order to provide suitable adhesive properties.

Apart from the problems in debonding, there is also the problem in the prior art of transferring layers produced on substrates onto product substrates, since a separating layer is also used for this, in order to separate the produced substrate stack from the carrier substrate.

The different methods are also distinguished in that, on the one hand, strong adhesive forces are required during processing irrespective of the process temperature, and on the other hand the substrates have to be separated from one another after the processing with the least possible forces.

It is the aim of the present invention, therefore, to specify a method for the separation of a carrier substrate and a substrate system for processing and transferring a substrate, which at least partially removes, in particular completely removes, the drawbacks stated in the prior art. In particular, it is the aim of the invention to specify an improved process and improved substrate system for the separation of substrates or the separation of layers on a substrate. It is furthermore an aim of the invention to specify an alternative method and an alternative substrate system, with the aid of which a substrate can be easily and cleanly processed, in particular released, debonded, or transferred. Furthermore, it is an aim of the present invention to specify a method and a substrate system, which operate low in contamination or enable such an operation. Furthermore, it is an aim of the present invention to specify a substrate system, from which in particular a carrier substrate can be separated or released in a particularly easy manner.

### SUMMARY OF THE INVENTION

The present invention is achieved with the features of the coordinated claims. Advantageous developments of the invention are given in the sub-claims. All combinations of at least two features stated in the description, in the claims and/or the drawings also fall within the scope of the invention. In the case of stated value ranges, values lying within the stated limits should also be deemed to be disclosed as limiting values and can be claimed in any combination.

Accordingly, the invention relates to a method for the separation of carrier substrate from a product substrate with at least the following steps:
i) Preparation of the carrier substrate and the product substrate with a separating layer arranged in between, wherein the separating layer fixes the product substrate on the carrier substrate,
ii) Irradiation of the separating layer with laser beams of a laser unit and
iii) Separation of the carrier substrate from the product substrate, characterised in that the separating layer is inorganic.

The separating layer at the same time functions as a bonding layer or adhesive layer for the, in particular, temporary fixing of the carrier substrate on the product substrate. The product substrate can be a substrate stack, a component or a single functional layer. In this regard, the method for the separation is basically also provided for the separation of any further substrate from the carrier substrate. The separating layer is particularly preferably arranged directly on the carrier substrate. In this way, a further bonding layer can advantageously be dispensed with. In addition, apart from the inorganic separating layer, preferably no further layers, in particular no organic layers, are required in the separation process. The degree of contamination is thus advantageously reduced.

In a further embodiment of the method, provision is made such that at least one further layer is arranged between the separating layer and the product substrate, and wherein the at least one further layer is inorganic.

In other words, a substrate system with at least the carrier substrate, the separating layer and a further layer can advantageously be processed with the method by a targeted laser treatment, such that the carrier substrate can be separated or released from the at least one further layer easily and with little contamination. In contrast with the prior art, a separating layer of carbon-free material is acted upon by means of a laser with laser beams, so that the adhesive properties of this inorganic separating layer are reduced, whilst the further layer is also inorganic. By means of the release of the carrier substrate by the action on the inorganic separating layer, a completely inorganic layer structure of the substrate system is possible. In various processes for the processing of substrates, in particular in the debonding and transferring of substrates, use of organic separating layers or bonding layers can thus advantageously be dispensed with.

The higher temperature resistance of inorganic materials enables a flexible design of the process. Furthermore, inorganic separating layers and bonding layers typically have a good thermal conductivity, so that a better dissipation of heat via the carrier substrate can take place.

Organic separating layers and organic bonding layers on a polymer base can disadvantageously also cause contamination in corresponding equipment and affect the quality unfavourably. With inorganic materials for the separating layer and the bonding layer, contamination of the equipment can thus be reduced.

The high adhesive properties of the inorganic separating layers and/or bonding layers also enable a thinner separating layer and thus overall a thinner layer structure in the substrate system to be processed. An improved planarity of the substrate system can thus be brought about and materials to be processed and thus contaminating can be spared. A further advantage of the method for separating carrier substrates consists in the lower energy input into the substrate system to be processed and a corresponding lower heat load, as a result of which in particular temperature-sensitive substrate systems can be processed.

The separating layer is formed from a carbon-free material and in particular is deposited previously on the carrier substrate. To this extent, the separating layer can also continue to serve at the same time as a bonding layer (temporary bonding) for the connection to the product substrate via the at least one further layer.

By a carrier substrate, any substrate is to be understood which is suitable for the application of the inorganic separating layer. The carrier substrate is preferably an inorganic substrate, particularly preferably a silicon wafer. Silicon wafers are particularly preferred.

The laser unit acts in a targeted manner and with matched parameters on the separating layer in different, preferably regularly spaced, areas. The inorganic layer preferably impermeable for the laser radiation of the laser unit absorbs the laser radiation, so that the adhesive properties and/or the stability of the separating layer are reduced locally. In particular, lateral cracks in the separating layer arise on account of the high local energy concentration, so that the carrier substrate can easily be released from the at least one further layer or the product substrate. By means of the inorganic separating layer, the carrier substrate can then be separated in a targeted manner from the at least one further layer in the method for the separation.

It is possible, even though not preferable, for an, in particular continuous, large-area laser irradiation to be conceivable. The laser beam does not move in this case relative to the substrate, but is widened in such a way that it strikes the substrate over the whole area. In particular, the irradiation time must be selected much longer in such a special embodiment.

In a preferred embodiment of the method, provision is made such that exclusively inorganic layers are arranged between the product substrate and the carrier substrate. The method can thus be carried out with particularly little contamination.

In a preferred embodiment of the method, provision is made such that laser beams emitted by the laser unit during the irradiation in step ii) first penetrate the carrier substrate and then strike the separating layer. In other words, the laser beams first pass through the carrier substrate and are then absorbed by the separating layer. The carrier substrate is thus at least partially transparent for the laser radiation. The laser unit can thus advantageously be arranged on the carrier side rear side and a separation can be carried out flexibly from the rear side, without special demands being made on the product substrate. In this connection, it should be pointed out that the, if applicable, at least one further layer at all events also absorbs the laser radiation so intensely that the product substrate is advantageously protected.

In a preferred embodiment of the method, provision is made such that the at least one further layer is a silicon oxide layer, which functions as a bonding layer. This inorganic bonding layer permits a separation process low in contamination.

In a preferred embodiment of the method, provision is made such that the at least one further layer is produced from a first oxide layer and a second oxide layer, in particular by fusion bonding. This further layer consisting of two oxide layers is particularly well suited for straightforward and stable bonding.

In a preferred embodiment of the method, provision is made such that the separating layer is made of a metal or nitride, preferably of a TiN. An inorganic separating layer made of metal or nitride is particularly suitable, since the latter in particular also enables a stable bond. A separating layer based on a tin is particularly preferred.

In a preferred embodiment of the method, provision is made such that the laser beam has a wavelength between 0.1 μm and 500 μm, preferably between 0.2 μm and 100 μm, still more preferably between 0.3 μm and 50 μm, most preferably between 0.5 μm and 10 μm, with utmost preference between 1 μm and 2.5 μm. The separating layer can thus be irradiated particularly efficiently and in a targeted manner. The carrier substrate is preferably transparent for the laser beams.

In a preferred embodiment of the method, provision is made such that the pulse energy of the laser beams amounts to between 0.01 μJ and 128 μJ, preferably between 0.125 μJ and 64 μJ, still more preferably between 0.25 μJ and 32 μJ, most preferably between 0.5 μJ and 16 μJ, with utmost preference between 1 μJ and 8 μJ. It has been shown that damage to the product substrate can be prevented with these pulse energies.

In a preferred embodiment of the method, provision is made such that the laser area is less than 2000 μm², preferably less than 500 μm², still more preferably less than 80 μm², most preferably less than 20 μm², with utmost preference less than 1 μm². The area of the separating layer on which the laser acts as advantageously small and local to reduce the adhesive properties of the separating layer and to destroy the latter.

In a preferred embodiment of the method, provision is made such that at least 0.1 μm, preferably at least 1 μm, more preferably at least 5 μm, still more preferably at least 10 μm, most preferably at least 50 μm lie between the areas in which the laser beam acts on the separating layer, so that the areas in which the laser beam acts do not overlap. In this way, a particularly easy and efficient separation is possible.

In a preferred embodiment of the method, provision is made such that the pulse duration of the laser beams amounts to between 10,000 ps and 1 ps, preferably between 1000 ps and 1 ps, still more preferably between 500 ps and 1 ps, most preferably between 100 ps and 1 ps, with utmost preference between 50 ps and 1 ps. This pulse duration permits a targeted action for the separation.

Furthermore, the invention relates to a substrate system, in particular for the production of semiconductor components, at least comprising,
A) a carrier substrate,
B) a separating layer arranged on the carrier substrate and
C) a product substrate arranged on the separating layer,
   wherein the carrier substrate can be separated from the product substrate by irradiation of the separating layer with a laser unit, characterised in that the separating layer is an inorganic layer and the separating layer fixes the product substrate on the carrier substrate.

In other words, the separating layer serves at the same time as a bonding layer. A simple and carbon-free structure is thus enabled.

In a preferred embodiment of the substrate system, provision is made such that at least one further layer is arranged between the separating layer and the product substrate and the product substrate is fixed on the carrier substrate by the at least one further layer, wherein the at least one further layer is inorganic.

A further functional layer with optimum properties for the given project is thus provided. In addition, the further layer is inorganic, so that the advantages of a carbon-free and inorganic stack continue to be present. If the further layer is a bonding layer, the adhesive properties between the carrier substrate/separating layer and the product substrate can advantageously be adjusted.

In a preferred embodiment of the substrate system, provision is made such that the at least one further layer is a bonding layer, wherein the bonding layer is produced at least from a first oxide layer and a second oxide layer, in particular by fusion bonding.

n a preferred embodiment of the substrate system, provision is made such that exclusively inorganic layers are arranged between the carrier substrate and the product substrate. The substrate system can thus be processed independently of the demands on the carbon-containing stacks. In addition, the contamination is reduced.

In a further preferred embodiment of the substrate system, provision is made such that the separating layer has a separating layer thickness between 10 nm and 500 nm. The small separating layer thickness permits a particularly easy and efficient separation of the carrier substrate. Furthermore, a particularly light substrate system with a small thickness can advantageously be produced, wherein at the same time a sufficient stabilisation is provided by the carrier substrate and a fixing by the separating layer or bonding layer.

Product substrate is understood to mean any kind of transferable component, in particular a wafer, a disc, but also small individual components such as chips, dies of differing complexity, form and functionality such as e.g. LEDs, MEMs etc. Carrier substrates are usually wafers and/or are suitable for supporting the layers arranged thereon.

In a special embodiment, provision is made such that, on the inorganic separating layer, there is an inorganic bonding layer, in particular of oxide, most preferably of a silicon oxide, which itself has been produced from the fusion bonding of two individual inorganic layers, whilst a further layer, in particular a functional layer, preferably made of semiconductor material, is located on this inorganic bonding layer. Since the inorganic bonding layer can be composed of two layers, it can be referred to as a layer stack. A further embodiment thus consists in a series of the following elements: Carrier substrate, inorganic separating layer, layer stack comprising at least two inorganic layers produced by fusion bond, functional layer or product substrate.

Furthermore, the invention relates to a device for the separation of carrier substrates, at least comprising:
a) a production unit for the production of the carrier substrate,
b) a laser unit for the irradiation of a separating layer arranged on the carrier substrate, wherein at least one further layer is arranged on the side of the separating layer facing away from the carrier substrate,
wherein the carrier substrate can be separated from the at least one further layer by irradiation of the separating layer, characterised in that the separating layer and the further layer are inorganic.

The device is suitable for reducing the adhesive properties of the inorganic separating layer and thus releasing or separating the carrier substrate of a substrate system. The laser unit and the material of the carrier substrate and the separating layer are matched to one another. In particular, the use of laser radiation in the range of infrared radiation in connection with the most preferred material combinations delivers optimum results. The optimum possibilities for the combination of laser parameters and materials are represented in tabular form in the disclosure as preferred embodiments.

An important aspect is that inorganic layers can be destroyed or the adhesive properties of inorganic layers can be changed with the method and the device. The inorganic layers are used as separating layers, in order to separate two substrates/layers joined together from one another or to release layers arranged on the separating layers from the substrate or the carrier substrate. Substrates and layers can thus be separated by the separating layer. The substrate with the separating layer can thus also be used so as to transfer other substrates/layers.

The method, the device and the substrate system can be used for the processing of a substrate, in particular for the separation of a product substrate from a carrier substrate. The concept of the single substrate also includes multi-layer substrate systems or substrate stacks.

An important aspect of the method and the device for the separation of a carrier substrate consists in the fact that exclusively inorganic layers are deposited on at least one carrier substrate, whereof at least one layer is a separating layer (or a release layer).

The separating layer is less than 10 μm, but typically less than a 100 nm, preferably less than 50 nm, still more preferably less than 25 nm, most preferably less than 10 nm, with utmost preference less than 1 nm.

This separating layer is bombarded during the separation of the substrates in particular by a beam, in particular a laser beam or a comparable high-intensity electromagnetic radiation source, or a particle beam. Use is preferably made of electromagnetic beams, in particular laser beams, less preferably particle beams.

The laser parameters preferably meet specific conditions, in order to separate the two substrates or the layers arranged on the side of the separating layer facing away from carrier substrate cleanly from one another, by the preferably optical influencing of the inorganic separating layer, with a small load for the product substrate and the carrier substrate. The use of organic layers on the substrate to be processed can thus advantageously be completely dispensed with. The use of the high temperature-resistant, inorganic separating layer thus enables processing steps, which include temperature ranges which would not be achievable for organic and thus less temperature-resistant layers, in particular polymer layers, without negatively influencing the adhesive force.

A further essential aspect consists in the fact that the energy of a laser is focused on the separating layer in order to bring about a reduction in adhesion and/or even a desirable sublimation of the separating layer, which drives the layers over the lateral radiation area apart from one another by an additional gas pressure and thus enables a high degree of efficiency in the release, insofar as the cohesion of the upper and lower adjacent layers is higher than the adhesion of the adjacent material and thus enables a crack formation along the layers and not obliquely thereto. It is necessary to match the carrier substrate material, the surface properties of the carrier substrate, the laser wavelength, the laser energy and in particular the duration of action—primarily defined by the laser pulse duration in the case of pulsed lasers—with one another. Since only very few efficient specific transmission processes exist in the infrared and visible spectral region, in contrast with the ultraviolet, which lead to molecular splitting (photochemical dissociation) by direct interaction on the chemical bonds, a “cold chemical” separation is not so easily possible. In this longwave spectral region low in photon energy, therefore, non-linear optical effects shorter thermal pulses are used. The latter are intentionally kept so short that a thermal propagation within the interaction duration of the pulse is limited to the separating layer as far as possible. Thus, and through the lateral limitation, heat is also prevented from acting in high concentration on the useful layer, but either is bound in the transformation processes (e.g. in the gas phase), or is distributed by the dissipation onto a much larger volume and a larger cross-sectional area, so that the temperatures fall by several orders of magnitude and do not lead to undesired damage to the substrates

In particular, the pulse duration should lie in the 1- to 2-digit picosecond range, because the heat concentration can be captured time-wise inside the layer at <1 μm layer thickness. On the other hand, undesired non-linear processes in the carrier substrate can thus be suppressed.

A development of the method and the device describes that, apart from the inorganic separating layer, a purely inorganic bonding layer is used to join two substrates or layers. The inorganic bonding layer is then arranged on the side of the separating layer facing away from the carrier substrate. An organic bonding layer enables a further distinction from the prior art, in that exclusively inorganic layers, in particular no polymer layers, are used as bonding layers. In this way, a transfer of substrates can also take place cleanly at raised temperatures, since neither the separating layer nor the bonding layer is made of organic material, in particular polymers tending towards carbonisation. The inorganic layers are also characterised in particular by having a very high degree of absorption (linear or non-linear), which enables in particular thin layers or also more complex layer systems.

The produced substrate stack is preferably exclusively inorganic. By means of the inorganic structure, the substrate stack, in particular the product substrate, can be processed at very high temperatures. A further advantage is the relatively high adhesive strength that predominates between the two substrates or the inorganic layers. The inorganic separating layers and, as the case may be, inorganic bonding layers can thus be designed thinner. The inorganic material of the separating layer can thus be advantageously matched to the different parameters of the laser unit. The laser unit can thus advantageously act in a targeted manner on the separating layer and not influence or only minimally influence further layers and/or the carrier substrate.

The method for processing a substrate consists in the, at least partial, removal or destruction or reduction of the adhesion of the inorganic separating layer. The transfer of other layers and/or a separation of the substrate, in particular carrier substrate, from another substrate is thus enabled.

In an embodiment of the method, an inorganic bonding layer is used in addition to the inorganic separating layer. The inorganic bonding layer brings about the joining of two substrates or a plurality of layers.

In the following section, the parameter ranges are described with which the method can be carried out, or the device operates.

The method is based on the fact that the laser beam of a laser, particularly preferably an infrared laser, is focused on the separating layer. The laser parameters must in particular meet some of the following criteria.

In the method and the device for the separation of carrier substrates, the following lasers or laser units are preferred.

### In the Ultraviolet Spectrum

F₂, ArF, Nd:YAG, He—Ag, KrF, XeCl, He—Cd, XeF

### In the Visible Spectrum

He—Cd, Ar, copper vapour, He—Ne, Kr, ruby

### In the Near Infrared Spectrum

Nd:YAG, He—Ne, Er:glass, Tm:YAG, Ho:YAG, Er:YSGG, Er:YAG

### In the Far Infrared Spectrum

methanol, methyl amine, methyl fluoride

The wavelength of the laser beam emitted by the laser unit lies between 0.1 μm and 500 μm, preferably between 0.2 μm and 100 μm, still more preferably between 0.3 μm and 50 μm, most preferably between 0.5 μm and 10 m, with utmost preference between 1 μm and 2.5 μm.

The following material classes and materials are preferably used for the separating layer
semiconductors, in particular
Ge
metals, in particular
Ti, W, Al, Ta, Cu
nitrides, in particular
TiN, TaN, WN, W₂N, WN₂

The laser or the laser unit is operated preferably in the pulse mode. A pulse duration as the short as possible is of particular interest. The short pulse duration provides for a local heat input in the separating layer and largely prevents thermal conduction into other layers. The pulse duration of the laser lies between 10,000 ps and 1 ps, preferably between 1000 ps and 1 ps, still more preferably between 500 ps and 1 ps, most preferably between 100 ps and 1 ps, with utmost preference between 50 ps and 1 ps.

The laser area or spot sizer is the effective cross-sectional area of the laser beam in the separating layer.

If the laser area is circular, it is preferably specified by a laser area diameter. The laser area diameter is less than 50 μm, preferably less than 25 μm, still more preferably less than 10 μm, most preferably less than 5 μm, with utmost preference less than 1 μm.

If the laser area is square, it is specified by a laser area side length. The laser area side length is less than 100 μm, preferably less than 80 μm, still more preferably less than 50 μm, most preferably less than 25 μm, with utmost preference less than 15 μm.

If the laser area is generally rectangular, it is specified by a first and a second laser area side length. The first and/or the second laser area side length is less than 100 μm, preferably less than 80 μm, still more preferably less than 50 μm, most preferably between 25 μm, with utmost preference less than 15 μm.

The average laser area is less than 2000 μm², preferably less than 500 μm², still more preferably less than 80 μm², most preferably less than 20 μm², with utmost preference less than 1 μm².

Disregarding convergence, the laser area corresponds approximately to the laser beam diameter along the length of the laser beam.

The introduced energy per pulse lies between 0.01 μJ and 128 μJ, preferably between 0.125 μJ and 64 μJ, still more preferably between 0.25 μJ and 32 μJ, most preferably between 0.5 μJ and 16 μJ, most preferably between 1 μJ and 8 μJ. The corresponding laser area energy density per pulse is calculated as the quotient of the energy per pulse to the laser area.

The roughness of the carrier substrate surface influences the scatter of the laser radiation. The roughness is preferably adjusted such that a maximum quantity of photons penetrate into the carrier substrate.

The roughness is specified either as an average roughness, a root-mean-squared roughness or as an averaged roughness depth. The determined values for the average roughness, the root-mean-squared roughness and the averaged roughness depth generally differ for the same measurement section or measurement area, but lie in the range of the same order of magnitude. The following numerical value ranges for the roughness are therefore to be understood either as values for the average roughness, the root-mean-squared roughness or for the averaged roughness depth.

The roughness is greater than 10 nm, preferably greater than 100 nm, still more preferably greater than 1 μm, most preferably greater than 10 μm, with utmost preference greater than 100 μm.

The distribution of the laser area energy along the position is not necessarily homogeneous. The laser area energy is in particular characterised by one of the following distribution functions:
Gaussian distribution,
Cauchy distribution,
Lorentz distribution
Pearson distribution or
Uniform distribution

A further important aspect of the method for the separation of a carrier substrate are the non-linear optical effects occurring during the irradiation of the separating layer with the laser unit

By the right combination of the correct physical parameters, in particular of the carrier substrate material, the pulse length, the laser wavelength, the laser energy, the behaviour of the electromagnetic wave or the photons in the carrier material can be adjusted in such a way that the focusing of the laser beam takes place in the separating layer. The electro-optical Kerr effect is decisively responsible for this, which describes the changes in the optical properties of a material, in particular the refractive index, as a function of the electrical field strength.

As a result of the selected laser parameters, and the spatially focused, short high-energy energy input generated therewith, at least one of the following physical effects arises.

The extreme temperature increase leads to a thermal expansion between the separating layer and the at least one further layer or substrate adjacent to the separating layer. This effect is all the more efficient, the greater the difference in the thermal expansion coefficients of the separating layer and the adjacent layers or substrates. Expansion coefficients are temperature-dependent, but lie in the order of magnitude of 10-6 K-1. A ratio is therefore useful. The absolute amount of the difference between the expansion coefficients of the separating layer and the expansion coefficient of at least one adjacent further layer or at least one adjacent substrate is greater than 0.1*10-6 K-1, preferably greater than 1.0*10-6 K-1, more preferably greater than 2.5*10-6 K-1, most preferably greater than 5.0*10-6 K-1, with utmost preference greater than 10.0*10-6 K-1. If the thermal expansion exceeds a critical value, the separating layer or the carrier substrate arranged on the other side of the separating layer can be separated or released from the at least one further layer or the substrate.

By means of a pulse duration selected very small, a greater quantity of heat can be introduced into the separating layer per unit of time than is carried away into the surrounding atmosphere. A sublimation and partially the formation of plasma thus arise as a result. If the pulse duration were selected too long, the inorganic separating layer would melt. As a result of the heat being carried away more rapidly into the surrounding atmosphere, a solidification of the melt very quickly occurs again and with it a renewed fusion of the separating layer with the surrounding atmosphere.

Melting of the inorganic separating layer is also conceivable. As already mentioned, it must be ensured when melting occurs that a renewed solidification of the melt does not fuse the separating layer again with its surroundings.

In a particularly preferred mode of procedure, the laser areas or laser spots do not overlap in the separating layer. In this case, the step width between two generated laser areas must be greater than the laser area of the laser beam. Each laser area in the separating layer or the area of action is exposed to a corresponding laser beam of the laser unit. The following parameter sets are intended to be stated by way of example. In the case of a preferred circular laser area with a laser area diameter of 10 μm, the step width lies between 10 μm and 30 μm, preferably between 10 μm and 25 μm, still more preferably between 10 μm and 20 μm, most preferably between 10 μm and 15 μm, with utmost preference between 10 μm and 12 μm. A step width should be selected which is greater than the laser area diameter, but is still large enough to effect an efficient weakening of the separating layer or the adhesion properties of the separating layer. For example, with a laser area diameter of 10 μm, it can be ensured that the weakening or destruction of the separating layer also takes place with a step width of 30 μm. In particular, it is not then necessary to reduce the step width to for example 15 μm or even 12 μm.

If the laser areas were to intersect, the sublimated inorganic material of the separating layer of the laser area could condense or re-sublimate in the adjacent laser area and lead to a renewed fusion. In the prior art, the polymer would absorb the sublimated separating layer material. It is thus an important aspect of all the embodiments of the method and the device for the separation of carrier substrates that a renewed fusion can be prevented by the correct selection of the step width between the laser areas with a given laser area. Furthermore, it should be mentioned that a laser does not function with a correspondingly small pulse duration in systems with organic layers.

The following layer system or substrate systems are provided for the separation during bonding or debonding.

In a first embodiment, the layer system consists only of an inorganic separating layer. The separating layer is preferably deposited on a substrate, in particular a carrier substrate. The separating layer acts at the same time as a bonding layer.

In a second embodiment, the layer system consists of at least a separating layer and a bonding layer. The separating layer is preferably deposited on a substrate, in particular a carrier substrate. The bonding layer is deposited on the separating layer. The task of the bonding layer consists in producing a connection to another substrate (at least one further layer), in particular a product substrate, whilst the separating layer has the task of being weakened or destroyed by means of a laser unit.

The following layer systems or substrates systems are provided for the layer transfer. The at least one further layer or the substrate stack can thus advantageously be transferred and uses for this purpose the process for the separation of carrier substrates.

In a third embodiment, the layer system consists of at least a separating layer and a transfer layer. The separating layer is preferably deposited on a substrate, in particular a carrier substrate. The transfer layer is deposited on the separating layer.

In a fourth embodiment, the layer system consists of a separating layer, a growth layer and a transfer layer. The separating layer is preferably deposited on a substrate, in particular a separating layer. The growth layer is deposited on the separating layer and is used to produce, in particular to grow, the transfer layer thereon.

In a fifth embodiment, the layer system consists of at least a separating layer, a growth layer, a mask and a transfer layer. The separating layer is preferably deposited on a substrate, in particular a carrier substrate. The growth layer is deposited on the separating layer. In particular, a mask is produced on the growth layer, in particular a hard material mask which has been produced by the combination of the deposition of a sol-gel, an imprint process and a curing process. By a deposition process, an overgrowth layer is generated, which grows proceeding from the growth layer through the apertures of the mask. This growth layer represents the transfer layer.

The mentioned layer systems or substrates systems can be used to implement the method for the separation.

In a first method, the separating layer is used for the debonding of the two substrates. For the sake of clarity and an overview, the method is described with the aid of two substrates, the carrier substrate and the product substrate. The method can however be used to produce a substrate stack with a plurality of substrates. In particular, it is conceivable that the inorganic layers, in particular the separating layer, vary between respectively two substrates. In the case of a plurality of substrates, there is preferably a carrier substrate and a plurality of product substrates applied thereon. It is also conceivable that the substrate stack consists only of product substrates. In this case, however, either at least one of the product substrates should be so thick that the substrate stack is mechanically sufficiently stabilised or the substrate stack in its entirety should be so thick that a mechanical stabilisation is present.

In a first process step, a separating layer is deposited on a carrier substrate. A bonding layer is deposited on the separating layer. The product substrate is bonded to this bonding layer.

In a second process step, the product substrate is processed.

In a third process step, the product substrate is bonded with its processed product substrate surface to another substrate, in particular a transfer substrate.

In a fourth process step, the separating layer is bombarded through the carrier substrate with a laser beam of a laser.

In a fifth process step, the carrier substrate is removed or released. In a special first process, layer systems comprising a separating layer and a bonding layer are used.

A separating layer is produced on a carrier substrate. A bonding layer is produced on the separating layer. A product substrate, in particular also provided with a bonding layer, is bonded to the bonding layer of the carrier substrate. The bond is preferably a fusion bond. The product substrate in particular already comprises functional units. In further process steps, the second, non-bonded, product substrate surface is processed. In particular, a back-thinning takes place to less than 100 μm, preferably less than 50 μm, still more preferably less than 25 μm, most preferably less than 10 μm, with utmost preference less than 5 μm. Further process steps, in particular also at high temperatures, can be carried out on the product substrate that has been thinned-back. Preferably, oxidation of the second product substrate surface takes place and TSVs are produced, so that the second product substrate surface becomes a hybrid bonding surface. A further fusion bonding of a second product substrate to the second product substrate surface of the first product substrate would be conceivable. This bond is then preferably a hybrid bond, i.e. the electrical contacts of the first product substrate are connected directly to the electrical contacts of the second product substrate, whilst the dielectric surrounding of the electrical contacts is connected together by a fusion bond. The product substrate surface of the second product substrate preferably again has a bonding layer. If the substrate stack consisting of a first and a second product substrate is mechanically stable enough, the process of separating layer weakening can be applied to the separating layer. The laser beam is focused on the separating layer preferably by the carrier substrate permeable or transparent for the specific wavelength of the laser. The separating layer thus loses its adhesive strength or is at least partially, preferably completely, removed. The two product substrates connected together can then be removed from the carrier substrate.

Exclusively inorganic layers are used, i.e. the separating layer and all the bonding layers are inorganic.

In a second method, the separating layer is used to transfer a transfer layer. This process is referred to as the layer transfer.

A carrier substrate is provided in a first process step. At least one separating layer is deposited on the carrier substrate. On the separating layer, at least one transfer layer is located. It is conceivable and preferable that a growth layer is deposited first on the separating layer and the transfer layer on the growth layer. It is also conceivable that the transfer layer is an overgrowth layer, which has to grow through a mask. The generation of such an overgrowth layer is described in detail in publication WO2016184523A1. It is also conceivable that a diffusion layer or a diffusion barrier has to be deposited between the separating layer and the transfer layer, in order that the two are not mixed with one another in further process steps.

In a second process step, the transfer layer is aligned with its free transfer layer surface with a product substrate. The product substrate can already comprise other functional units and/or other layers. It would also be conceivable for the substrate to be a transfer substrate which receives the transfer layer only temporarily and in a further process step transfers it to a product substrate. In this case, a corresponding inorganic separating layer can also be produced on the transfer substrate.

In third process step, the transfer layer is bonded with the product substrate.

In a fourth process step, the separating layer is bombarded with the laser beam, so that it either loses the adhesive strength and/or is at least partially destroyed.

In a fifth process step, the carrier substrate is removed and the transfer layer remains on the product substrate. In particular, the growth layer also remains on the transfer layer.

In a sixth process step, a possibly still present growth layer is removed from the transfer layer.

The difference in the exemplary process for the separation consists in particular in that, on the one hand, two substrates are separated from one another and, on the other hand, a layer is transferred. An inorganic separating layer is required for all the stated processes.

In the following, an exemplary list of preferred materials and process parameters is disclosed, with the aid of which a separating layer can be used in a particular optimum manner for the separation by a laser bombardment.

| | System 1 | System 2 | System 3 | System 4 |
|---|---|---|---|---|
| Carrier substrate material | Silicon | Sapphire | Quartz | SiC |
| Carrier substrate thickness | 300-1500 μm | 300-1500 μm | 300-1500 μm | 300-1500 μm |
| Separating layer material | TiN, TaN, Ti | TiN, TaN, Ti | TiN, TaN, Ti | TiN, TaN, Ti |
| | WN, W₂N, | WN, W₂N, | WN, W₂N, | WN, W₂N, |
| | WN₂ | WN₂ | WN₂ | WN₂ |
| Separating layer thickness | 10 nm-500 nm | 10 nm-500 nm | 10 nm-500 nm | 10 nm-500 nm |
| Laser pulse length | 100 fs - 100 ns | 100 fs-100 ns | 100 fs-100 ns | 100 fs-100 ns |

Further advantages, features and details of the invention emerge from the following description of preferred examples of embodiment and with the aid of the drawings. In the drawings, diagrammatically:

### BRIEF DESCRIPTION OF THE DRAWINGS

FIG. 1a shows a side view of a substrate with a separating layer which can also act as a bonding layer,

FIG. 1b shows a side view of a substrate with a separating layer and a separate bonding layer,

FIG. 2a shows a side view of a substrate with a separating layer and the transfer layer,

FIG. 2b shows a side view of a substrate with a separating layer, a growth layer and a transfer layer,

FIG. 2c shows a side view of a substrate with a separating layer, a growth layer, a mask and transfer layer,

FIG. 3a shows a first process step of an exemplary first method,

FIG. 3b shows a second process step of a first method, FIG. 3c shows a third process step of a first method,

FIG. 3d shows a fourth process step of a first method,

FIG. 3e shows a fifth process step of a first method,

FIG. 4a shows a first process step of an exemplary first special method,

FIG. 4b shows a second process step of a first special method, FIG. 4c shows a third process step of a first special method,

FIG. 4d shows a fourth process step of a first special method, FIG. 4e shows a fifth process step of a first special method,

FIG. 4f shows a sixth process step of a first special method,

FIG. 4g shows a seventh process step of a first special method, FIG. 4h shows an eighth process step of a first special method,

FIG. 4i shows a ninth process step of a first special method,

FIG. 5a shows a first process step of an exemplary second method,

FIG. 5b shows a second process step of a second method,

FIG. 5c shows a third process step of a second method,

FIG. 5d shows a fourth process step of a second method,

FIG. 5e shows a fifth process step of a second method and

FIG. 5f shows a sixth process step in the method.

Identical components or components with the same function are denoted by the same reference numbers in the figures.

### DETAILED DESCRIPTION OF THE INVENTION

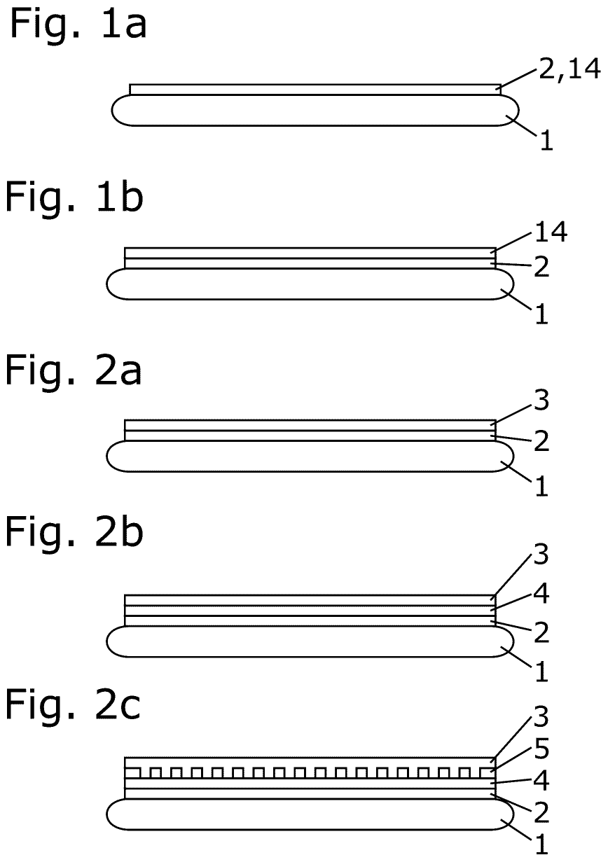

FIGS. 1a-1b show two basic substrate systems or layer systems on a carrier substrate 1, the purpose of which consists in the provision of a separating layer 2 and a bonding layer 14. All layers are inorganic.

FIG. 1a shows a side view of a carrier substrate 1, on which a separating layer 2 has been deposited. Separating layer 2 is inorganic. Separating layer 2 is deposited directly on substrate 1 with a method known from the prior art. This combination of carrier substrate 1 and separating layer can be used for the bonding of a second substrate. Separating layer 2 acts in this case not only as a separating layer, but at the same time also as a bonding layer 14. In this case, the carrier substrate 1 would be a carrier substrate, the purpose of which consists in stabilising the second substrate mechanically.

FIG. 1b shows a side view of a carrier substrate 1, on which a separating layer 2 has been deposited. Separating layer 2 is inorganic. On separating layer 2, there is a bonding layer 14, to which another substrate, which preferably also has a bonding layer 14, can be bonded. Bonding layer 14 is inorganic, preferably a dielectric, in particular an oxide layer, most preferably a silicon oxide layer.

FIGS. 2a-2c show four basic substrate systems or layer systems. In addition to the inorganic separating layer, they comprise at least one further layer. Furthermore, the carrier substrate provides separating layer 2 and a transfer layer 3. All the layers of the substrate system are inorganic. These layer systems serve for the transfer of transfer layer 13 onto another substrate (not shown), in particular a product substrate 6 and not for the bonding of carrier substrate 1 to a substrate (not shown), in particular product substrate 6. Transfer layer 3 is designed as wide as possible. A transfer layer 3 can thus be understood to mean a single layer, but also a layer system. Transfer layer 3 can for example also be an imprinted layer with structures. Transfer layer 3 can for example be a layer comprising a plurality of lenses, microchips, MEMs, LEDs, etc. The thickness of transfer layer 3 can amount to several Ångströms up to several millimetres.

FIG. 2a shows a side view of a carrier system 1, on which a separating layer 2 has been deposited. Separating layer 2 is inorganic. Located on separating layer 2 is a transfer layer 3, which is to be transferred onto another substrate (not shown), in particular a product substrate 6.

FIG. 2b shows a side view of a carrier substrate 1, on which a separating layer 2 has been deposited. Separating layer 2 is inorganic. A growth layer 4 is located on separating layer 2. The transfer layer 3 is produced on growth layer 4. The transfer layer 3 can be transferred in a process onto another substrate (not shown), in particular product substrate 6. FIG. 2b is a special case of FIG. 2a. Generally, a separating layer 2 will not offer the necessary prerequisites for producing a desired transfer layer 3, so that a growth layer 4 must first be produced, on which transfer layer 3 can be grown.

FIG. 2c shows a side view of a carrier substrate 1, on which a separating layer 2 has been deposited. Separating layer 2 is inorganic. A growth layer 4 is present on separating layer 2. A mask is applied on growth layer 4. Mask 5 is preferably imprinted by an imprinting process directly from a liquid, preferably a sol-gel, and cured. Mask 5 can however be produced by any other process. The material for a transfer layer 3 is then deposited. The material of transfer layer 3 is first deposited in the openings of mask 5 and grows via the latter to form a full-area transfer layer 3. Such a transfer layer 3 is called an overgrowth layer. Transfer layer 3 can be transferred in a process for the separation onto another substrate (not shown), in particular product substrate 6. FIG. 2c is a special case of FIG. 2b. In addition to growth layer 4, a mask has also been produced. The advantage in the production of such a transfer layer 3 consists in the fact that it is for the most part defect-free.

A bonding layer 14 can also be deposited on said transfer layers 3, in order to increase the adhesive strength to the substrate (not shown), in particular product substrate 6, on which transfer layer 3 is to be transferred. Since the representation of such a bonding layer 14 has already been shown in FIGS. 1a-1b, it is omitted in FIGS. 2a-2c for the sake of clarity.

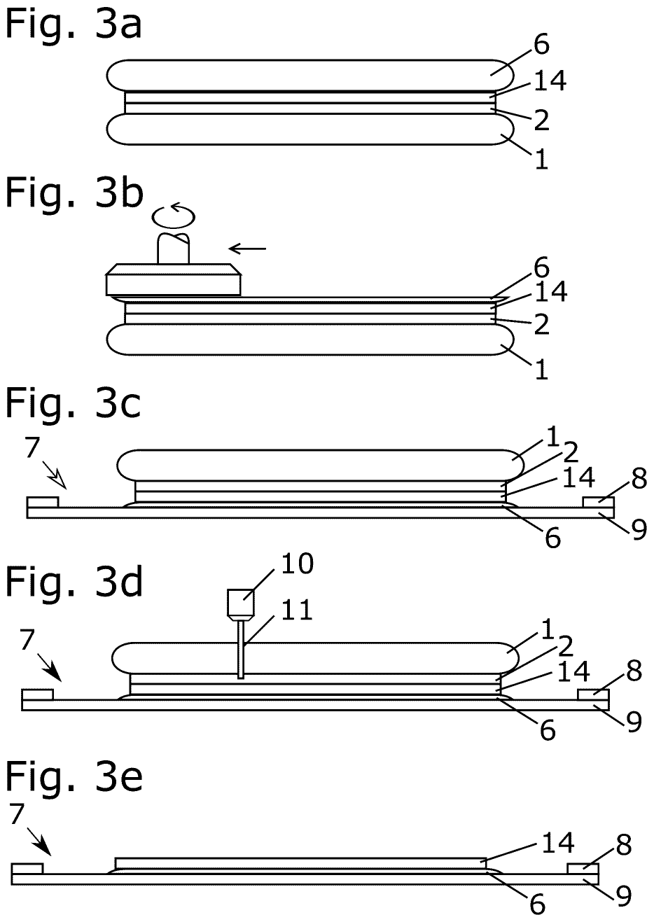

FIG. 3a shows a side view of a first process step of a first possible method. A carrier substrate 1, on which a separating layer 2 and a bonding layer 14 are present (see FIG. 1b), is aligned and bonded to a product substrate 6. Product substrate 6 is bonded to bonding layer 14 via a first product substrate surface. Carrier substrate 1 has the task in the further process of stabilising product substrate 6 mechanically.

FIG. 3b shows a side view of a second process step of a first possible method. The second product substrate surface of product substrate 6 is processed. Back-thinning of product substrate 6 is represented by way of example. In this process step, however, innumerable other processes can be carried out. In particular, LEDs, MEMS, microcontrollers etc. can be produced. In order to keep the representation as simple as possible, the representation of these processes is omitted.

FIG. 3c shows a side view of a third process step of a first possible method. Product substrate 6 is aligned and bonded to a transfer substrate 7 via a processed second product substrate surface. In the present case, transfer substrate 7 is a film 9, which has been stretched on a frame 8. Transfer substrate 7 can however be another substrate, in particular a further carrier substrate 1 or another product substrate 6.

FIG. 3d shows a side view of a fourth process step of a first possible method. A laser 10 is used to focus a laser beam 11 onto separating layer 2. By the use of a laser 10 with corresponding laser parameters, in particular a very short pulse duration in the picosecond range, separating layer 2 is released or the adhesive strength to carrier substrate 1 is reduced at least so far that carrier substrate 1 can be removed.

FIG. 3e shows a side view of a fifth process step of a first possible method. Product substrate 6, after removal of carrier substrate 1 (not shown, see FIG. 3d), is located on the transfer substrate 7. Separating layer 2 has been removed or has already been automatically removed in the process step according to FIG. 3d.

The further figures show a second method, to which decisive importance is attributed in the semiconductor industry. The second method is generalised and abstracted as far as possible. The use of an inorganic separating layer 2 and a bonding layer 14 of its own is however characteristic.

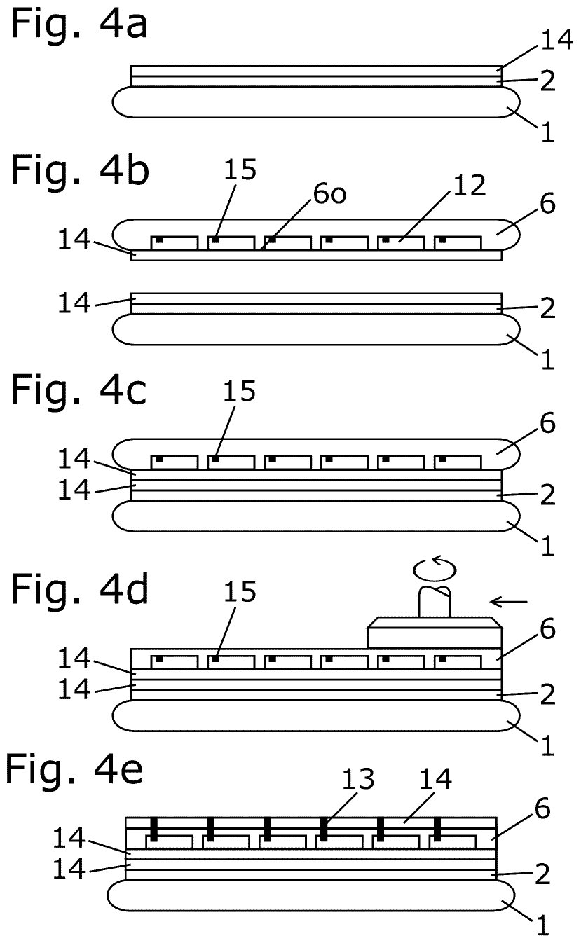

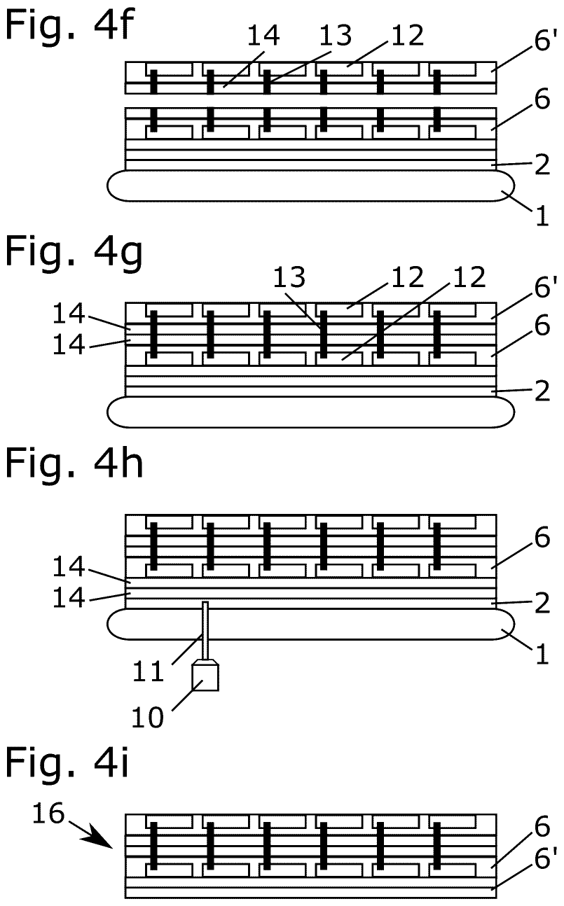

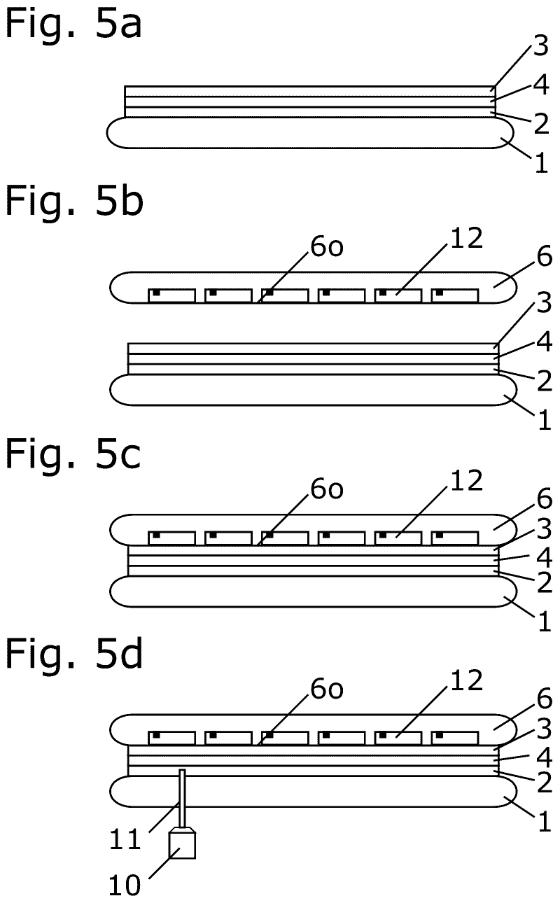

FIG. 4a shows a side view of a first process step of a first special method. A separating layer 2 is deposited on a carrier substrate 1. A bonding layer 14 is produced on separating layer 2 (see FIG. 1b). Bonding layer 14 is preferably a dielectric layer, most preferably an oxide, with utmost preference a silicon oxide.

FIG. 4b shows a side view of a second process step of a first special method. A product layer 6 already provided with functional units 12, the product substrate surface 60 of which has preferably been coated with a bonding layer 14, is aligned relative to carrier substrate 1. Functional units 12 preferably comprise electrical contacts 15. The use of a bonding layer 14 on product substrate 6 can be dispensed with, if product substrate 6 with a product substrate surface 60 adheres sufficiently well to bonding layer 14 of carrier substrate 1. Bonding layer 14 is however preferably present on product substrate 6, still more preferably the materials of the two bonding layers 14 on carrier substrate 1 and on product substrate 6 are identical. Most preferably of all, the bonding layers are oxides.

FIG. 4c shows a side view of third process step of a first special method. Product substrate 6 is bonded via bonding layers 14 to carrier substrate 1. If the bonding layers are an oxide, then it is in this case a fusion bond. Before a possible heat treatment, one still speaks of a so-called pre-bond. After heat treatment, after covalent bonds have been formed between the contacting bonding layer surfaces of bonding layers 14, one speaks of a fusion bond. The process step of the heat treatment is not represented. It is important that product substrate 6 adheres sufficiently well to carrier substrate 1, in order for it to be further processed. If the adhesive strength without heat treatment is high enough, it is even conceivable not to carry out any heat treatment.

FIG. 4d shows a side view of fourth process step of a first special method. Back-thinning of product substrate 6 takes place here. Back-thinning is very often desired, in order to minimise the thickness of the end product as far as possible.

FIG. 4e shows a side view of fifth process step of a first special method. The black-thinned product substrate surface of product substrate 6 is coated with a bonding layer 14, in particular a dielectric layer, preferably an oxide, with utmost preference with a silicon oxide. Through silicon vias (TSVs) 13 are produced through bonding layer 14 and product substrate 6, in order to make electrical contacts 15 of functional units 12 on the surface of bonding layer 14 accessible and available.

FIG. 4f shows a side view of a sixth process step of a first special method. A second product 6′, also provided with functional units 12, TSVs 13 and bonding layer 14, is aligned relative to first product substrate 6 or to carrier substrate 1. Second product substrate 6′ is probably also fixed on a carrier substrate 1′, preferably even with the aid of the method. In order not to make the figures to complicated, however, the representation of a carrier substrate l′ with the corresponding separating layer 2 and bonding layer 14 or any other layer system is omitted. The alignment takes place by means of alignment marks (not shown) and the alignment systems with very precise optics (not shown) specially provided for the purpose.

FIG. 4g shows a side view of seventh process step of a first special method. The two product substrates 6, 6′ are bonded together by means of their bonding layers 14. TSVs 13 are correctly bonded with one another, so that an electrical connection between functional units 12 of product substrates 6, 6′ is possible.

FIG. 4h shows a side view of a seventh process step of a first special method. A laser 10 is used in order to focus a laser beam 11 on separating layer 2. By using a laser 10 with corresponding laser parameters, in particular a very short pulse duration in the picosecond range, separating layer 2 is released or the adhesive strength to carrier substrate 1 is at least reduced so far that carrier substrate 1 can be removed.

FIG. 4i shows a side view of a seventh process step of a first special method. A substrate stack 16 permanently bonded together can be seen, consisting of two product substrates 6, 6′. This substrate stack can be further processed correspondingly. It was mentioned in FIG. 4i that the representation of a carrier substrate l′ would be omitted for reasons of clarity. On such a carrier substrate l′, substrate stack 16 would be able to be further transported and/or further processed without problem.

A separating layer 2 with a bonding layer 14 located thereon was used and described in FIGS. 4a-4i. According to the general embodiment from FIG. 1a, separating layer 2 and bonding layer 14 can also be identical.

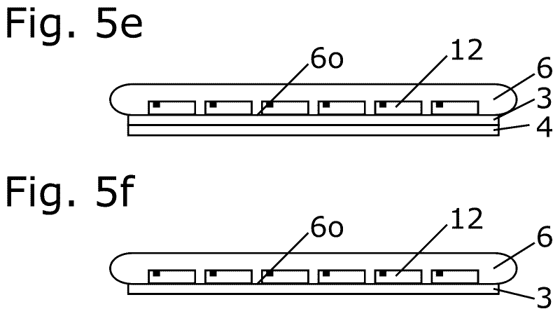

FIG. 5a shows a side view of a first process step of a second method, in which a carrier substrate 1 is provided with at least one separating layer 2 and one transfer layer 3. Preferably, growth layer 4 it also located on separating layer 2, in order to be able to produce, in particular to grow, transfer layer 3.

FIG. 5b shows a side view of a second process step of a second method, in which a product substrate 6, preferably with functional units 13, is aligned relative to the carrier substrate. The alignment again takes place with the aid of alignment marks (not shown) and with special alignment systems (not shown).

FIG. 5c shows a side view of a third process step of a second method, in which product substrate 6 is contacted by transfer layer 3. In the present case, it is desirable that transfer layer 3 directly contacts functional units 12. It is conceivable, for example, that in subsequent process steps structuring of transfer layer 3 takes place. Transfer layer 3 could for example be a graphene layer, which has been grown on growth layer 4 made of copper. On the product substrate surface of product substrate 6, an RDL layer (engl.: redistribution layer) can then be produced from transfer layer 3.

FIG. 5d shows a side view of a fourth process step of a second method, in which a laser beam 11 of a laser 10 is focused on separating layer 2.

FIG. 5e shows a side view of a fifth process step of a second method, in which carrier substrate 1 (not shown, see FIG. 5d) has been removed.

FIG. 5f shows a side view of a sixth process step of a second method, in which growth layer 4 has also been removed.

### LIST OF REFERENCE NUMBERS

1 carrier substrate
2 separating layer
3 transfer layer
4 growth layer
5 mask
6, 6′ product substrate
7 transfer substrate
8 frame
9 film
10 laser unit, laser
11 laser beam
12 functional unit
13 TSV
14 bonding layer
15 electrical contacts
16 substrate stack

1. A method for the separation of a carrier substrate from a product substrate, comprising:
providing the carrier substrate and the product substrate with an inorganic separating layer arranged in between, the separating layer being configured to fix the product substrate on the carrier substrate;
irradiating the separating layer with laser beams of a laser unit; and
separating the carrier substrate from the product substrate.

2. The method according to claim 1, wherein at least one further layer is arranged between the separating layer and the product substrate, and
wherein the at least one further layer is inorganic.

3. The method according to claim 1, wherein exclusively inorganic layers are arranged between the product substrate and the carrier substrate.

4. The method according to claim 1, wherein the irradiated laser beams first penetrate the carrier substrate and then strike the separating layer.

5. The method according to claim 2, wherein the at least one further layer is a silicon oxide layer acting as a bonding layer.

6. The method according to claim 2, wherein the at least one further layer is produced from a first oxide layer and a second oxide layer by fusion bonding.

7. The method according to claim 2, wherein the separating layer) is made from a metal or nitride.

8. The method according to claim 1, wherein the laser beam has a wavelength between 0.1 μm and 500 μm.

9. The method according to claim 1, wherein a pulse energy of the laser beam amounts to between 0.01 μJ and 128 μJ.

10. The method according to claim 1, wherein a laser area is less than 2000 μm².

11. The method according to claim 1, wherein at least 0.1 μm lie between areas in which the laser beam acts on the separating layer, so that the areas in which the laser beam acts do not overlap.

12. The method according to claim 1, wherein a pulse duration of the laser beam amounts to between 10,000 ps and 1 ps.

13. A substrate system for the production of semiconductor components, comprising:
a carrier substrate;
a product substrate arranged on the separating layer; and
an inorganic separating layer arranged in between the carrier substrate and the product substrate,
wherein the carrier substrate is separable from the product substrate by irradiation of the separating layer with a laser unit, and
wherein the separating layer fixes the product substrate on the carrier substrate.

14. The substrate system according to claim 13, wherein at least one further layer is arranged between the separating layer and the product,
wherein the product substrate is fixed to the carrier substrate by the at least one further layer, and
wherein the at least one further layer is inorganic.

15. The substrate system according to claim 14, wherein the at least one further layer is a bonding layer, and
wherein the bonding layer is produced at least from a first oxide layer and a second oxide layer by fusion bonding.

16. The substrate system according to claim 13, wherein exclusively inorganic layers are arranged between the carrier substrate and the product substrate.

17. The substrate system according to claim 13, wherein the separating layer has a separating layer thickness between 10 nm and 500 nm.

18. The method according to claim 7, wherein the separating layer is made from TiN.
